(19) United States
(12) Patent Application Publication
(10) Pub. No.: US 2026/0190342 A1
(43) Pub. Date: Jul. 2, 2026

(54) SEMICONDUCTOR DEVICE

(71) Applicant: Samsung Electronics Co., Ltd., Suwon-si (KR)

(72) Inventors: Hyojoon RYU, Suwon-si (KR); Jae-Hwang SIM, Suwon-si (KR); Seongjae GO, Suwon-si (KR); Kangmin KIM, Suwon-si (KR); Yunna UM, Suwon-si (KR); Euntaek JUNG, Suwon-si (KR); Byeong-In CHOE, Suwon-si (KR)

(73) Assignee: Samsung Electronics Co., Ltd., Suwon-si (KR)

(21) Appl. No.: 19/248,742

(22) Filed: Jun. 25, 2025

(30) Foreign Application Priority Data
Dec. 27, 2024 (KR) 10-2024-0197952

(51) Int. Cl. H10B 43/35; H10B 43/10; H10B 43/27

(52) U.S. Cl. CPC H10B 43/35; H10B 43/10; H10B 43/27

(57) ABSTRACT

Provided is a semiconductor device with improved electrical characteristics and reliability. The semiconductor device may include a substrate, a mold stack including a plurality of gate electrodes and a plurality of mold insulating layers alternately stacked on the substrate, an interlayer insulating film on the mold stack, a string select line stack on the interlayer insulating film and including a string select line gate layer, a through via penetrating the mold stack, the interlayer insulating film, and the string select line stack, and an insulating pattern surrounding the through via within the string select line gate layer. The string select line gate layer includes a first gate portion between an inner surface of the insulating pattern and an outer surface of the through via, and a second gate portion on an outer surface of the insulating pattern.

### CROSS-REFERENCE TO RELATED APPLICATION

This U.S. non-provisional application claims priority under 35 U.S.C. § 119 to Korean Patent Application No. 10-2024-0197952, filed in the Korean Intellectual Property Office on Dec. 27, 2024, the entire contents of which are hereby incorporated by reference.

### BACKGROUND

Example embodiments relate to a semiconductor device.

Electronic systems that use data storage may benefit from semiconductor devices that store high-capacity data. Studies are being performed to increase the data storage capacity of semiconductor devices. For example, one way of increasing the data storage capacity of the semiconductor device may include a three-dimensional arrangement of memory cells instead of a two-dimensional arrangement of memory cells.

### SUMMARY

Example embodiments are directed to a semiconductor device having improved electrical characteristics and reliability.

According to some example embodiments, a semiconductor device includes a substrate, a mold stack including a plurality of gate electrodes and a plurality of mold insulating layers alternately stacked on the substrate, an interlayer insulating film on the mold stack, a string select line stack on the interlayer insulating film and including a string select line gate layer, a through via penetrating the mold stack, the interlayer insulating film, and the string select line stack, and an insulating pattern surrounding the through via within the string select line gate layer. The string select line gate layer may include a first gate portion between an inner surface of the insulating pattern and an outer surface of the through via, and a second gate portion on an outer surface of the insulating pattern.

According to some example embodiments, a semiconductor device includes a substrate, a mold stack including a plurality of gate electrodes and a plurality of mold insulating layers alternately stacked on the substrate, an interlayer insulating film on the mold stack, a string select line stack on the interlayer insulating film and including a string select line gate layer, a through via penetrating the mold stack, the interlayer insulating film, and the string select line stack, and an insulating pattern surrounding the through via within the string select line gate layer. An inner surface of the insulating pattern and an outer surface of the insulating pattern may be symmetrical to each other and may have the same inclination angle.

According to some example embodiments, a semiconductor device includes a substrate, a mold stack including a plurality of gate electrodes and a plurality of mold insulating layers alternately stacked on the substrate, an interlayer insulating film on the mold stack, a string select line stack including a first string select line insulating layer, a second string select line insulating layer, a string select line gate layer, and a third string select line insulating layer, which are sequentially on the interlayer insulating film, a through via penetrating the mold stack, the interlayer insulating film, and the string select line stack, and an insulating pattern surrounding the through via within the string select line gate layer. The insulating pattern may be spaced apart from an outer surface of the through via.

According to some example embodiments, a method for manufacturing a semiconductor device may include forming a preliminary mold stack in which a plurality of mold insulating layers and a plurality of mold sacrificial layers are alternately stacked on the substrate, forming a preliminary through via through the preliminary mold stack, forming a string select line stack on the preliminary mold stack, forming an insulating pattern in the string select line gate layer of the string select line stack, forming a select line stack through hole through the string select line stack, patterning the string select line gate layer in a horizontal direction, removing the preliminary through via and forming a through via hole, and forming a through via inside the through via hole.

According to some example embodiments, the forming the string select line stack may include forming a first string select line insulating layer on the interlayer insulating film on the preliminary mold stack, forming a second string select line insulating layer on the first string select line insulating layer, forming the string select line gate layer on the second string select line insulating layer, and forming the third string select line insulating layer on the string select line gate layer.

According to some example embodiments, a donut-shaped insulating pattern is formed on the string select line gate layer, and a string select line gate layer is partially maintained between the insulating pattern and the through via, so that process conditions can be kept constant. Accordingly, the electrical performance of the semiconductor device can be improved.

According to some example embodiments, a system includes a controller, and a semiconductor device communicably coupled to the controller. The semiconductor device includes a substrate, a mold stack including a plurality of gate electrodes and a plurality of mold insulating layers alternately stacked on the substrate, an interlayer insulating film on the mold stack, a string select line stack on the interlayer insulating film and including a string select line gate layer, a through via penetrating the mold stack, the interlayer insulating film, and the string select line stack, and an insulating pattern surrounding the through via within the string select line gate layer. The string select line gate layer may include a first gate portion between an inner surface of the insulating pattern and an outer surface of the through via, and a second gate portion on an outer surface of the insulating pattern. According to some example embodiments, the string select line stack further includes a first string select line insulating layer on the interlayer insulating film, a second string select line insulating layer between the first string select line insulating layer and the string select line gate layer, and a third string select line insulating layer on the string select line gate layer. According to some example embodiments, the through via includes a first portion and a second portion penetrating the interlayer insulating film, the first portion is below the first string select line insulating layer, the second portion is below the first portion, and a horizontal width of the first portion is greater than a horizontal width of the second portion. According to some example embodiments, the through via includes a stepped surface defined by a difference in width between the first portion and the second portion. According to some example embodiments, the through via further includes a third portion penetrating the third string select line insulating layer, and the horizontal width of the first portion is greater than a horizontal width of the third portion.

Various and beneficial advantages and effects of the present disclosure are not limited to those described above, and can be more easily understood in the course of describing example embodiments of the present disclosure.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIG. 1 is an example layout of a semiconductor device, according to some example embodiments.

FIG. 2 is a cross-sectional view taken along line A-A of FIG. 1.

FIG. 3 is an enlarged view of a region R1 of FIG. 2.

FIG. 4 is an enlarged view of a region R2 of FIG. 2.

FIG. 5 is an enlarged view of a region R3 of FIG. 2.

FIG. 6 is a cross-sectional view taken along line B-B in FIG. 5.

FIGS. 7, 8, and 9 illustrate enlarged views of the region R3 of FIG. 2.

FIGS. 10, 11, and 12 illustrate the semiconductor device of FIG. 2, according to some example embodiments. FIGS. 10 and 12 illustrate enlarged views of the region R3 of FIG. 2. FIG. 11 is a cross-sectional view taken along line C-C of FIG. 10.

FIG. 13 illustrates a semiconductor device, according to some example embodiments.

FIG. 14 illustrates a semiconductor device, according to some example embodiments.

FIGS. 15, 16, 17, 18, 19, and 20 illustrate intermediate stages in a method for manufacturing a semiconductor device, according to some example embodiments.

FIG. 21 is an example block diagram of an electronic system, according to some example embodiments.

FIG. 22 is a perspective view illustrating an electronic system including a semiconductor device, according to some example embodiments.

FIG. 23 is a schematic cross-sectional view taken along line V-V of FIG. 22.

### DETAILED DESCRIPTION

Hereinafter, various aspects of the example embodiments will be described with reference to the drawings. Throughout the description, the same reference numerals may refer to the same components.

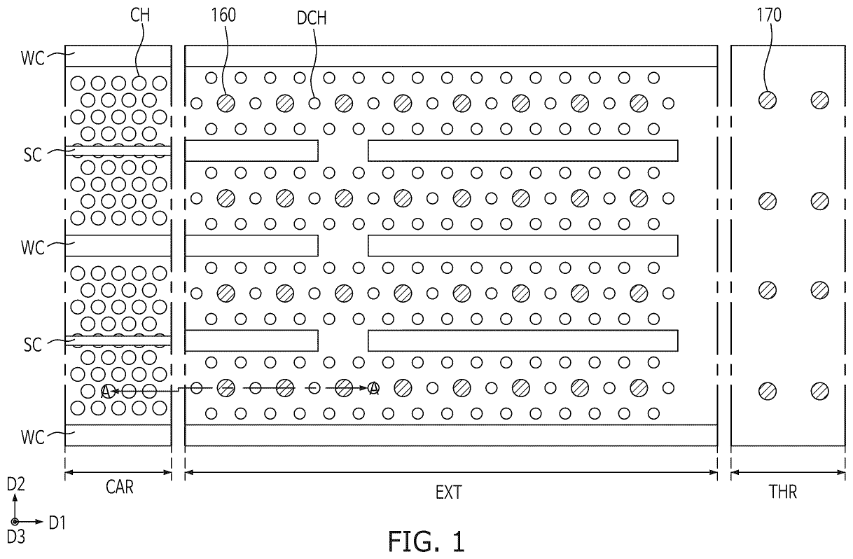

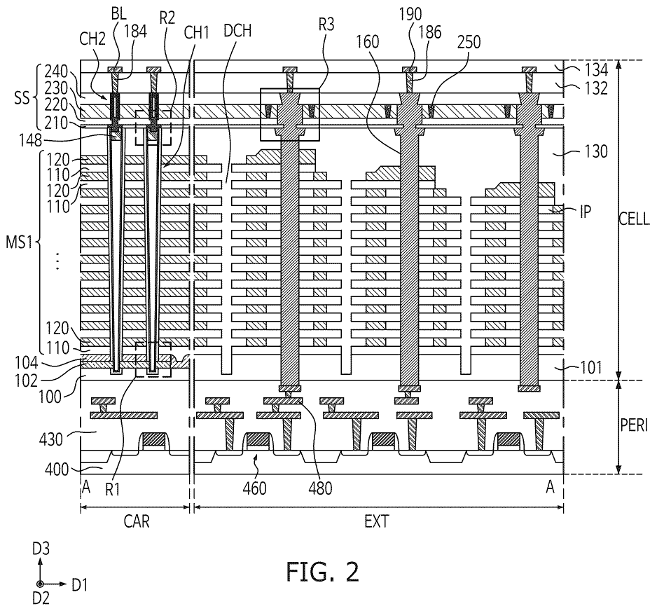

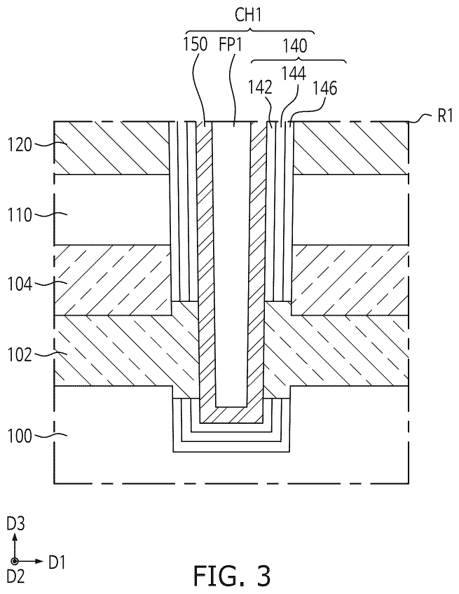

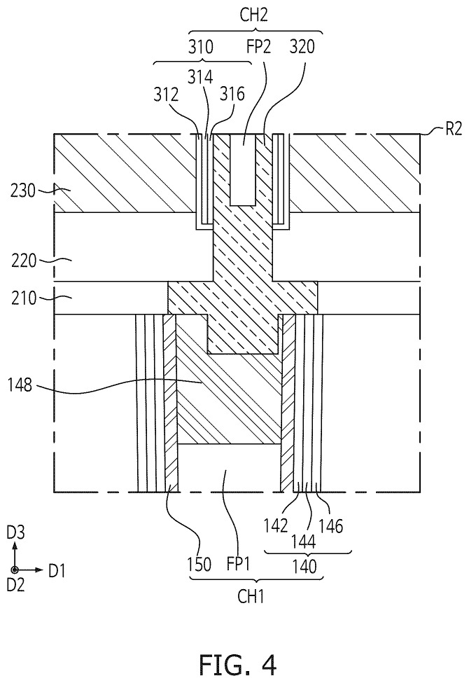

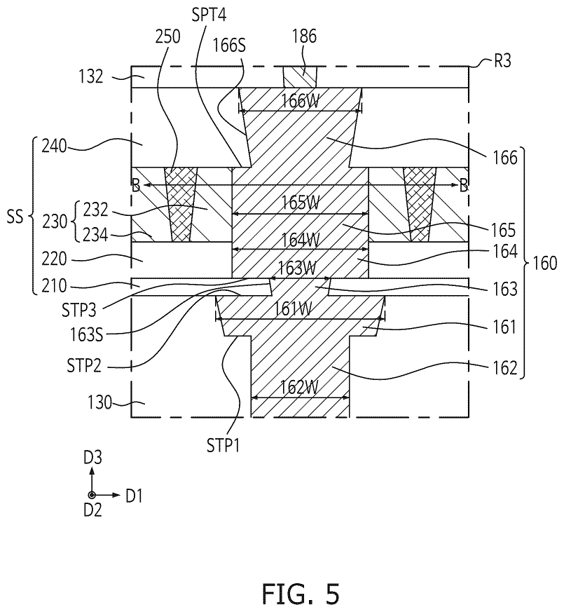

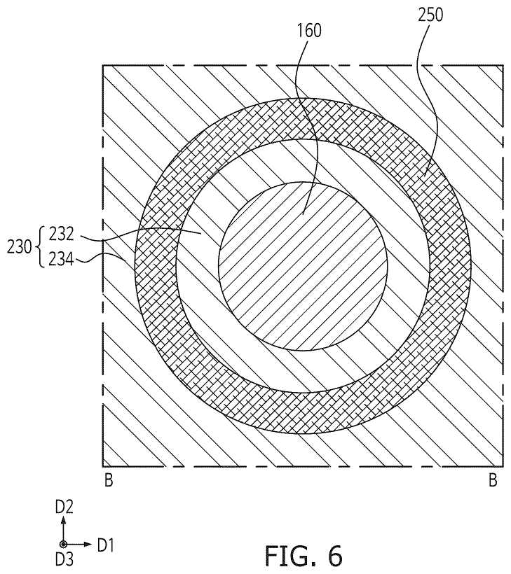

FIG. 1 is an example layout of a semiconductor device, according to some example embodiments. FIG. 2 is a cross-sectional view taken along line A-A of FIG. 1. FIG. 3 is an enlarged view of a region R1 of FIG. 2. FIG. 4 is an enlarged view of a region R2 of FIG. 2. FIG. 5 is an enlarged view of a region R3 of FIG. 2. FIG. 6 is a cross-sectional view taken along line B-B in FIG. 5.

Referring to FIGS. 1 to 6, a semiconductor device may include a cell region CELL and a peripheral circuit region PERI.

The cell region CELL may include a cell substrate 100, an insulating substrate 101, a first mold stack MS1, a first interlayer insulating film 130, channel structures CH1 and CH2, a channel pad 148, a block isolation pattern WC, a bit line BL, a first through via 160, a second through via 170, a first wiring structure 190, etc.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate, a germanium-on-insulator (GOI) substrate, etc. The cell substrate 100 may include polysilicon (poly Si).

The cell substrate 100 may include a cell array region CAR and an extension region EXT.

A memory cell array including a plurality of memory cells may be formed in the cell array region CAR. For example, the first channel structure CH1, the bit line BL, gate electrodes 120, etc., which will be described below, may be disposed in the cell array region CAR. In the following description, the surface of the cell substrate 100 on which the memory cell array is disposed may be referred to as a front side of the cell substrate 100. Conversely, the surface of the cell substrate 100 opposite to the front side of the cell substrate 100 may be referred to as a back side of the cell substrate 100.

The extension region EXT may be disposed around the cell array region CAR. For example, the extension region EXT may surround the cell array region CAR. The first through via 160, which will be described below, may be disposed in the extension region EXT. In addition, the gate electrodes 120 may be stacked in a stepwise manner in the extension region EXT. However, example embodiments are not limited to the above. For example, each of the gate electrodes 120 and each of mold insulating layers 110 alternately stacked on the cell substrate 100 and/or the insulating substrate 101 in the extension region EXT may have a layered structure extending parallel to an upper surface of the cell substrate 100.

The cell substrate 100 may further include a through region THR. The through region THR may be disposed inside the cell array region CAR and the extension region EXT, or it may be disposed outside the cell array region CAR and the extension region EXT. The second through via 170, which will be described below, may be disposed in the through region THR.

The insulating substrate 101 may be formed in the cell substrate 100 in the extension region EXT. The insulating substrate 101 may form an insulating region in the cell substrate 100 in the extension region EXT. The insulating substrate 101 may include at least one of, for example, silicon oxide, silicon nitride, silicon oxynitride, and silicon carbide, but is not limited thereto. The insulating substrate 101 may be formed in the cell substrate 100 of the through region THR. In the description, the cell substrate 100 and the insulating substrate 101 may be referred to collectively as a “substrate”.

Although a lower surface of the insulating substrate 101 is illustrated in the same plane as a lower surface of the cell substrate 100, this is merely an example. According to some example embodiments, the lower surface of the insulating substrate 101 may be lower than the lower surface of the cell substrate 100, or alternatively, the lower surface of the insulating substrate 101 may be higher than the lower surface of the cell substrate 100.

The first mold stack MS1 may be formed on the front side of the cell substrate 100. The first mold stack MS1 may include a plurality of gate electrodes 120 and a plurality of mold insulating layers 110 stacked on the cell substrate 100. Each of the gate electrodes 120 and each of the mold insulating layers 110 may have a layered structure extending parallel to the front side of the cell substrate 100. The gate electrodes 120 may be spaced apart from each other by the mold insulating layers 110 and sequentially stacked on the cell substrate 100.

The first mold stack MS1 may include the gate electrodes 120 and the mold insulating layers 110 alternately stacked on the cell substrate 100. Some of the plurality of gate electrodes 120 may include a ground select line GSL and an erase select line ECL. For example, among the plurality of gate electrodes 120, a gate electrode 120 adjacent to source structures 102 and 104 may be provided as the erase select line ECL. The erase select line ECL may be provided as a gate electrode of an erase transistor. The erase transistor may generate a gate induced drain leakage (GIDL) to perform an erase operation on a plurality of memory cell transistors. A gate electrode 120 adjacent to the erase select line ECL may be provided as a ground select line GSL. However, example embodiments are not limited to the above. The arrangement and number of the ground select lines GSL may vary. In some example embodiments, the erase select line ECL may be omitted.

Each of the gate electrodes 120 may include a conductive material, for example, a metal such as tungsten (W), cobalt (Co), and nickel (Ni), or a semiconductor material such as silicon, but is not limited thereto.

Each of the mold insulating layers 110 may include at least one of an insulating material, for example, silicon oxide, silicon nitride, and silicon oxynitride, but is not limited thereto.

The first interlayer insulating film 130 may be formed on the cell substrate 100 to cover the first mold stack MS1. The first interlayer insulating film 130 may include at least one of, for example, silicon oxide, silicon oxynitride, and a low-k material having a lower dielectric constant than silicon oxide, but is not limited thereto.

The first channel structure CH1 may be formed within the first mold stack MS1 in the cell array region CAR. The first channel structure CH1 may extend in a vertical direction (hereinafter, a third direction D3) that intersects with the upper surface of the cell substrate 100 and penetrate through the first mold stack MS1. For example, the first channel structure CH1 may have a pillar shape (e.g., a cylinder shape or column shape) extending in the third direction D3. Accordingly, the first channel structure CH1 may intersect with each of the gate electrodes 120.

As illustrated in FIGS. 3 and 4, the first channel structure CH1 may include an information storage film 140, a first semiconductor pattern 150, and a first filling pattern FP1 sequentially stacked on side surfaces of the mold insulating layers 110 and the gate electrodes 120. For example, a channel hole may be formed through or penetrating the first mold stack MS1 in the third direction D3. The information storage film 140, the first semiconductor pattern 150, and the first filling pattern FP1 may be sequentially formed in the channel hole to form a stacked structure.

The information storage film 140 may be interposed between the gate electrodes 120 and the first semiconductor pattern 150. For example, an inner surface of the information storage film 140 may be connected to or may contact an outer surface of the first semiconductor pattern 150, and an outer surface of the information storage film 140 may be connected to or may contact the gate electrodes 120. The information storage film 140 may be disposed at an outermost portion of the first channel structure CH1. The information storage film 140 may have a shape of a hollow tube (e.g., a cylindrical shape), but example embodiments are not limited thereto.

For example, the information storage film 140 may include at least one of silicon oxide, silicon nitride, silicon oxynitride, and a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

The information storage film 140 may include multiple films. The information storage film 140 may include a tunnel insulating film 142, a charge storage film 144, and a blocking insulating film 146, which may be sequentially stacked or formed on the outer surface of the first semiconductor pattern 150.

For example, the tunnel insulating film 142 may include the silicon oxide or a high-k material (e.g., aluminum oxide (Al₂O₃), hafnium oxide (HfO₂)) having a higher dielectric constant than the silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

The first semiconductor pattern 150 may be interposed between the information storage film 140 and the first filling pattern FP1. For example, an inner surface of the first semiconductor pattern 150 may be connected to or may contact an outer surface of the first filling pattern FP1, and the outer surface of the first semiconductor pattern 150 may be connected to or may contact the information storage film 140. The first semiconductor pattern 150 may have a cup shape or U shape, but example embodiments are not limited thereto. For example, the first semiconductor pattern 150 may have various shapes such as a cylindrical shape, a rectangular cylindrical shape, a filled pillar shape, etc.

The first semiconductor pattern 150 may include, for example, a semiconductor material such as single crystal silicon, polycrystalline silicon, an organic semiconductor material, and a carbon nanostructure, but example embodiments are not limited thereto.

The first filling pattern FP1 may fill an inner space of the first semiconductor pattern 150. The first filling pattern FP1 may have, for example, a pillar shape or column shaped. For example, the first filling pattern FP1 may have a cylindrical shape filling the interior of the first semiconductor pattern 150 which has a hollow cup shape. The first filling pattern FP1 may include an insulating material, for example, silicon oxide, but example embodiments are not limited thereto.

The channel pad 148 may be disposed on an inner upper portion of the first semiconductor pattern 150. For example, the channel pad 148 may fill an upper portion of the inner space of the first semiconductor pattern 150. The channel pad 148 may be disposed on the first filling pattern FP1. The channel pad 148 may be electrically connected to or may contact the first semiconductor pattern 150. An upper surface of the channel pad 148 may be disposed in the same plane or level as an upper surface of the first mold stack MS1. The upper surface of the first mold stack MS1 may be an upper surface of the mold insulating layer 110 disposed at the top among the plurality of mold insulating layers 110 or an upper surface of the first interlayer insulating film 130. For example, the channel pad 148 may include polysilicon doped with impurities, but example embodiments are not limited thereto.

A plurality of first channel structures CH1 may be arranged in a zigzag form. For example, as illustrated in FIG. 1, the plurality of first channel structures CH1 may be arranged to alternate with each other in a first direction D1 and a second direction D2 which are parallel to the upper surface of the cell substrate 100. The plurality of first channel structures CH1 arranged in the zigzag form may further improve or increase the integration density of the semiconductor device. The plurality of first channel structures CH1 may be arranged in a honeycomb form.

A dummy channel structure DCH may be formed in the first mold stack MS1 in the extension region EXT. The dummy channel structure DCH may extend in the third direction D3 and penetrate through the first mold stack MS1 in the extension region EXT. The dummy channel structure DCH may reduce stress applied to the first mold stack MS1 in the extension region EXT.

The dummy channel structure DCH may include horizontal insulating patterns extending in a horizontal direction (e.g., the first and second directions D1 and D2) at a vertical level corresponding to each of the gate electrodes 120. Each of the horizontal insulating patterns may surround or extend around a portion of a body of the dummy channel structure DCH extending in the third direction D3. Each of the horizontal insulating patterns may overlap with each of the gate electrodes 120 in the first direction D1. The horizontal insulating patterns may include multiple films. However, example embodiments are not limited to the above.

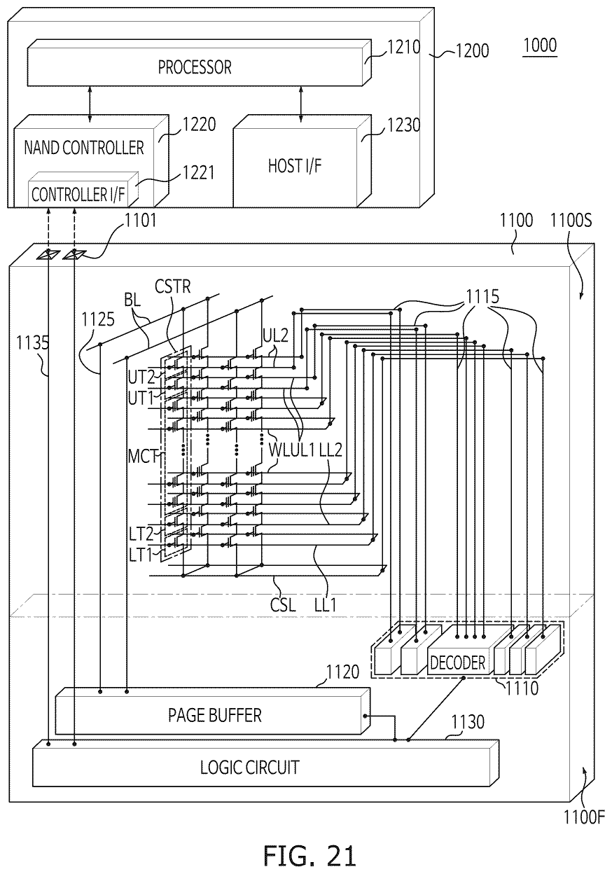

The source structures 102 and 104 may be formed on the cell substrate 100. For example, the source structures 102 and 104 may extend along the front side of the cell substrate 100. The source structures 102 and 104 may be connected to or may contact the first semiconductor pattern 150 and/or the information storage film 140 of the first channel structure CH1. The source structures 102 and 104 may be provided as a common source line (e.g., CSL of FIG. 21) of the semiconductor device. For example, the source structures 102 and 104 may include polysilicon or metal doped with impurities, but example embodiments are not limited thereto.

The source structures 102 and 104 may include multiple films. For example, the source structures 102 and 104 may include a first source layer 102 and a second source layer 104, which are sequentially stacked on the cell substrate 100. Each of the first source layer 102 and the second source layer 104 may include polysilicon doped with an impurity or polysilicon undoped with an impurity, but example embodiments are not limited thereto. The first source layer 102 may be provided as the common source line (e.g., CSL of FIG. 21) of the semiconductor device. The second source layer 104 may be provided as a support layer for preventing the mold stack from collapsing or falling down in a replacement process for forming the first source layer 102.

A base insulating film may be interposed between the cell substrate 100 and the source structures 102 and 104. The base insulating film may include at least one of, for example, silicon oxide, silicon nitride, and silicon oxynitride, but example embodiments are not limited thereto.

The source structures 102 and 104 may not be formed within the extension region EXT in which the insulating substrate 101 is formed. An upper surface of the insulating substrate 101 is illustrated as being in the same plane as the upper surfaces of the source structures 102 and 104, but this is merely an example. In some example embodiments, the upper surface of the insulating substrate 101 may be higher than the upper surfaces of the source structures 102 and 104. In some example embodiments, the upper surface of the insulating substrate 101 may be lower than the upper surfaces of the source structures 102 and 104.

The block isolation patterns WC may extend in the first direction D1 to cut the first mold stack MS1. For example, at least some of the block isolation patterns WC may extend continuously in the first direction D1 to completely cut through the first mold stack MS1. Some others of the block isolation patterns WC may be configured in an arrangement in which the block isolation patterns WC are spaced apart from each other in one column to partially cut the first mold stack MS1.

A string select line stack SS may be disposed on the first mold stack MS1. For example, the string select line stack SS may be disposed on the first interlayer insulating film 130 that covers the first mold stack MS1.

The string select line stack SS may include a first string select line insulating layer 210, a second string select line insulating layer 220, a string select line gate layer 230, and a third string select line insulating layer 240, which are sequentially stacked or formed on the first interlayer insulating film 130.

The first string select line insulating layer 210 may be disposed on the first interlayer insulating film 130. The first string select line insulating layer 210 may be disposed along the upper surface of the first interlayer insulating film 130. The first string select line insulating layer 210 may extend in the first and second directions D1 and D2.

The second string select line insulating layer 220 may be disposed on the first string select line insulating layer 210. The second string select line insulating layer 220 may be disposed along an upper surface of the first string select line insulating layer 210. The second string select line insulating layer 220 may be disposed between the first string select line insulating layer 210 and the string select line gate layer 230. The second string select line insulating layer 220 may extend in the first and second directions D1 and D2.

Each of the first string select line insulating layer 210 and the second string select line insulating layer 220 may include an insulating material. The first string select line insulating layer 210 may include a material different from that of the second string select line insulating layer 220. The first string select line insulating layer 210 may have etch selectivity with respect to the second string select line insulating layer 220. For example, the first string select line insulating layer 210 may include silicon nitride, and the second string select line insulating layer 220 may include silicon oxide. However, example embodiments are not limited thereto.

The string select line gate layer 230 may be disposed on the second string select line insulating layer 220. The string select line gate layer 230 may be disposed along an upper surface of the second string select line insulating layer 220. The string select line gate layer 230 may be provided as a gate electrode, for example, a string select line SSL of string select transistors UT1 and UT2 of FIG. 21.

The string select line gate layer 230 may include a material different from that of the gate electrode 120. For example, the string select line gate layer 230 may include a semiconductor material such as polycrystalline silicon. In this case, a thickness of the string select line gate layer 230 in the third direction D3 may be greater than a thickness of the gate electrode 120 in the third direction D3. However, example embodiments are not limited to the above. For example, the string select line gate layer 230 may include the same material as the gate electrode 120. The string select line gate layer 230 may include at least one of, for example, a metal (e.g., TiN or TaN) and a transition metal (e.g., Ti or Ta).

The third string select line insulating layer 240 may be disposed on the string select line gate layer 230. The third string select line insulating layer 240 may be disposed along an upper surface of the string select line gate layer 230. The third string select line insulating layer 240 may extend in the first and second directions D1 and D2. The third string select line insulating layer 240 may include, for example, one of silicon oxide, silicon nitride, and silicon oxynitride.

The second channel structure CH2 may be formed within the string select line stack SS in the cell array region CAR. The second channel structure CH2 may extend in the third direction D3 and penetrate through the string select line stack SS. For example, the second channel structure CH2 may have a pillar shape (e.g., a cylinder shape or column shape) extending in the third direction D3. Accordingly, the second channel structure CH2 may intersect with the string select line gate layer 230.

The second channel structure CH2 may be located, formed, or arranged on the first channel structure CH1. The second channel structure CH2 may be formed through or penetrating the string select line stack SS and connected to or may contact the first channel structure CH1. For example, the second channel structure CH2 may be formed through or penetrating the first string select line insulating layer 210, the second string select line insulating layer 220, the string select line gate layer 230, and the third string select line insulating layer 240 and connected to or may contact the first channel structure CH1 exposed on the upper surface of the first interlayer insulating film 130. The second channel structure CH2 may be provided as a string select channel structure of the string select transistors UT1 and UT2 of FIG. 21.

As illustrated in FIG. 4, the second channel structure CH2 may include a dielectric pattern 310, a second semiconductor pattern 320, and a second filling pattern FP2.

The dielectric pattern 310 may be disposed at an outermost portion of the second channel structure CH2. The dielectric pattern 310 may extend in the third direction D3, through the third string select line insulating layer 240 and the string select line gate layer 230, and into the second string select line insulating layer 220. The dielectric pattern 310 may be interposed between inner surfaces of the third string select line insulating layer 240, the string select line gate layer 230, and the second string select line insulating layer 220 and an outer surface of the second semiconductor pattern 320. The dielectric pattern 310 may have a shape of a hollow tube (e.g., a cylindrical shape), but example embodiments are not limited thereto.

The dielectric pattern 310 may include a first dielectric layer 312, a second dielectric layer 314, and a third dielectric layer 316. For example, the first dielectric layer 312, the second dielectric layer 314, and the third dielectric layer 316 may be sequentially stacked or formed on side surfaces of the third string select line insulating layer 240, the string select line gate layer 230, and the second string select line insulating layer 220. The first dielectric layer 312 may surround or extend around lower surfaces of the second dielectric layer 314 and the third dielectric layer 316. However, example embodiments are not limited to the above.

The first dielectric layer 312 may include, for example, silicon oxide or a high-k material (e.g., aluminum oxide (Al₂O₃) or hafnium oxide (HfO₂)) having a higher dielectric constant than silicon oxide. For example, the second dielectric layer 314 may include silicon nitride. The third dielectric layer 316 may include, for example, silicon oxide or a high-k material (e.g., aluminum oxide (Al₂O₃) or hafnium oxide (HfO₂)) having a higher dielectric constant than silicon oxide.

The second semiconductor pattern 320 may fill an inner space of the dielectric pattern 310. In addition, the second semiconductor pattern 320 may extend in the third direction D3, through the third string select line insulating layer 240, the string select line gate layer 230, the second string select line insulating layer 220, and the first string select line insulating layer 210, and into the channel pad 148. The second semiconductor pattern 320 may have a hollow cup shape or U shape, but example embodiments are not limited thereto.

The outer surface of the second semiconductor pattern 320 may include a portion connected to or contacting the dielectric pattern 310. In addition, the outer surface of the second semiconductor pattern 320 may include a portion connected to or contacting the second string select line insulating layer 220 and the first string select line insulating layer 210. In addition, a lower portion of the second semiconductor pattern 320 may include a portion connected to or contacting the channel pad 148.

The second semiconductor pattern 320 may include a portion extending from the body of the second semiconductor pattern 320 in a horizontal direction (e.g., in the first and second directions D1 and D2) at a portion connected to or contacting the first string select line insulating layer 210. Accordingly, the second semiconductor pattern 320 may be connected to or may contact the first semiconductor pattern 150 exposed on the upper surface of the first interlayer insulating film 130.

The second semiconductor pattern 320 may include, for example, a semiconductor material such as single crystal silicon, polycrystalline silicon, an organic semiconductor material, and a carbon nanostructure, but example embodiments are not limited thereto.

The second filling pattern FP2 may fill an inner space of the second semiconductor pattern 320. The second filling pattern FP2 may have a columnar shape, for example. For example, the second filling pattern FP2 may have a cylindrical shape filling the interior of the second semiconductor pattern 320 which has a hollow cup shape or U shape. The second filling pattern FP2 may include an insulating material, for example, silicon oxide, but example embodiments are not limited thereto.

The string isolation structure SC may extend in the first direction D1 to cut the string select line gate layer 230. The divided string select lines may independently control each region. The string isolation structure SC may include at least one of an insulating material, for example, silicon oxide, silicon nitride, and silicon oxynitride, but is not limited thereto.

A second interlayer insulating film 132 may be disposed on the string select line stack SS. For example, the second interlayer insulating film 132 may be disposed on the third string select line insulating layer 240. The second interlayer insulating film 132 may include an insulating material. For example, it may include one of silicon oxide, silicon nitride, and silicon oxynitride.

The bit line BL may be formed on the second interlayer insulating film 132. The bit line BL may extend in the second direction D2 and intersect with the block isolation pattern WC. In addition, the bit line BL may extend in the second direction D2 and be connected to or may contact a plurality of second channel structures CH2 arranged along the second direction D2. For example, a bit line contact 184 connected to or contacting an upper portion of each of the second channel structures CH2 may be formed within the second interlayer insulating film 132. The bit line BL may be electrically connected to or may contact the first channel structures CH1 and the second channel structures CH2 through the bit line contact 184.

The first through via 160 may be formed within the first mold stack MS1 and the string select line stack SS in the extension region EXT. The first through via 160 may extend in the third direction D3 and penetrate through the first mold stack MS1 and the string select line stack SS. For example, the first through via 160 may have a pillar shape (e.g., a cylinder shape) extending in the third direction D3. Accordingly, the first through via 160 may intersect with each of the gate electrodes 120.

The first through via 160 may be connected to or may contact each of the corresponding gate electrodes 120. For example, the first through via 160 may be connected to or may contact a corresponding gate electrode (e.g., a select gate electrode) among the plurality of gate electrodes 120. In addition, the first through via 160 may not contact the remaining, non-corresponding gate electrodes (e.g., non-select gate electrodes) among the plurality of gate electrodes 120. Furthermore, the first through via 160 may be formed through or penetrating the insulating substrate 101 and electrically connected to or may contact a peripheral circuit structure PERI to be described below.

The semiconductor device may further include a through via insulating pattern IP disposed between the first through via 160 and the non-select gate electrode among the plurality of gate electrodes 120. The through via insulating pattern IP may surround or extend around a portion of a sidewall of the first through via 160. The through via insulating pattern IP may overlap with the non-select gate electrode among the plurality of gate electrodes 120 in the first direction D1. The through via insulating pattern IP may include multiple films. However, example embodiments are not limited to the above.

The first through via 160 with varying widths may be formed through or penetrating the first interlayer insulating film 130 and the string select line stack SS. As illustrated in FIGS. 5 and 6, the first through via 160 may include a first portion 161 and a second portion 162 formed through or penetrating the first interlayer insulating film 130. The first portion 161 may be disposed below the first string select line insulating layer 210 and may include a portion connected to or contacting a lower surface of the first string select line insulating layer 210. In addition, the second portion 162 may be disposed below the first portion 161 and may include a portion extending in the third direction D3 through the first mold stack MS1.

A horizontal width 161W of the first portion 161 may be greater than a horizontal width 162W of the second portion 162. In the present disclosure, the “horizontal width” may represent an average of the widths in the horizontal direction (e.g., the first direction D1 or the second direction D2) over the entire vertical level of the component or a specific portion of the component, or represent a width of the component in the horizontal direction at any vertical level (e.g., at a vertical level corresponding to an upper surface, a middle surface, or a lower surface).

Additionally or alternatively, a side surface of the first portion 161 and a side surface of the second portion 162 may be misaligned in the third direction D3. For example, the first through via 160 may include a first stepped surface STP1 defined by the difference in width between the first portion 161 and the second portion 162.

This may be due to a process of forming a through hole when forming the first through via 160. For example, first, an opening for forming the first through via 160 may be formed on the upper surface of the first interlayer insulating film 130, and then using the opening, a through hole may be formed through or penetrating the first interlayer insulating film 130 and the first mold stack MS1. In this process, the horizontal width 161W of the first portion 161 may be formed greater than the horizontal width 162W of the second portion 162.

Additionally, the first through via 160 may further include a third portion 163 formed through or penetrating the first string select line insulating layer 210, a fourth portion 164 formed through or penetrating the second string select line insulating layer 220, a fifth portion 165 formed through or penetrating the string select line gate layer 230, and a sixth portion 166 formed through or penetrating the third string select line insulating layer 240.

The horizontal width 161W of the first portion 161 may be greater than a horizontal width 166W of the sixth portion 166. Additionally or alternatively, the side surface of the first portion 161 and the side surface of the third portion 163 may be misaligned in the third direction D3. For example, the first through via 160 may include a second stepped surface STP2 defined by the difference in width between the first portion 161 and the third portion 163.

This may be due to the characteristics of the process of forming the through hole and the opening in the first interlayer insulating film 130 and the string select line stack SS. For example, first, the through hole for forming the first through via 160 may be formed in the first interlayer insulating film 130, and then the opening may be formed on the string select line stack SS to be connected to or contact the through hole of the first interlayer insulating film 130. In this process, a difference may occur between the width of the opening formed on the upper surface of the first interlayer insulating film 130 and the width of the opening formed on the upper surface of the third string select line insulating layer 240.

A horizontal width 163W of the third portion 163 may be less than the horizontal width 161W of the first portion 161 and a horizontal width 164W of the fourth portion 164. In addition, a side surface of the third portion 163 and a side surface of the fourth portion 164 may be misaligned in the third direction D3. For example, the first through via 160 may include a third stepped surface STP3 defined by the difference in width between the third portion 163 and the fourth portion 164.

A horizontal width 165W of the fifth portion 165 may be greater than the horizontal width 166W of the sixth portion 166. In addition, a side surface of the fifth portion 165 and a side surface of the sixth portion 166 may be misaligned in the third direction D3. For example, the first through via 160 may include a fourth stepped surface STP4 defined by the difference in width between the fifth portion 165 and the sixth portion 166.

This may be due to characteristics of the process of forming and patterning the string select line stack SS connected to or contacting the first interlayer insulating film 130. For example, first, an opening may be formed in the string select line stack SS to connect or contact the through hole of the first interlayer insulating film 130, and then the second string select line insulating layer 220 and the string select line gate layer 230 may be patterned in the horizontal direction (e.g., in the first and second directions D1 and D2). Accordingly, a width of the opening formed on the first string select line insulating layer 210 may be less than a width of the opening formed on the upper surface of the first interlayer insulating film 130 and/or a width of the opening formed on the second string select line insulating layer 220. In addition, a width of the opening formed on the string select line gate layer 230 may be greater than a width of the opening formed on the third string select line insulating layer 240.

A side surface 163S of the third portion 163 and a side surface 166S of the sixth portion 166 may have the same inclination angle. This may be due to the characteristics of the process of forming an opening in the string select line stack SS, which penetrates the string select line stack SS in the third direction D3 to contact the through hole of the first interlayer insulating film 130. For example, the opening may be formed through or penetrating the first string select line insulating layer 210, the second string select line insulating layer 220, the string select line gate layer 230, and the third string select line insulating layer 240. In this process, since no additional patterning process is performed in the horizontal direction for the openings formed in the first string select line insulating layer 210 and the third string select line insulating layer 240, the side surface 163S of the third portion 163 and the side surface 166S of the sixth portion 166 may have the same or similar inclination angles.

An insulating pattern 250 may be formed within the string select line gate layer 230. The insulating pattern 250 may surround or extend around the first through via 160 within the string select line gate layer 230. The insulating pattern 250 may have a hollow cylindrical shape or a donut shape. The insulating pattern 250 may include an insulating material, for example, silicon oxide, but example embodiments are not limited thereto. The insulating pattern 250 may include the same material as that of the second string select line insulating layer 220, but example embodiments are not limited thereto.

The insulating pattern 250 may be disposed to be spaced apart from an outer surface of the first through via 160. A portion of the string select line gate layer 230 may be interposed between the insulating pattern 250 and the first through via 160. As illustrated in FIGS. 5 and 6, the string select line gate layer 230 may include a first gate portion 232 disposed between an inner surface of the insulating pattern 250 and an outer surface of the first through via 160 and a second gate portion 234 disposed on an outer surface of the insulating pattern 250.

The inner surface of the insulating pattern 250 and the outer surface of the insulating pattern 250 may be symmetrical to each other and have the same inclination angle. For example, the inner surface of the insulating pattern 250 and the outer surface of the insulating pattern 250 may have inclinations slanted in different directions, and may be symmetrical to each other based on a vertical direction (e.g., the third direction D3). Accordingly, angles formed between a virtual line extending from a lower surface of the string select line gate layer 230 and each of the outer and inner surfaces of the insulating pattern 250 may be the same or substantially the same as each other.

The second through via 170 may be disposed in the through region THR. A structure in which the mold insulating layer 110 and a mold sacrificial film are stacked may be formed on the cell substrate 100 and/or the insulating substrate 101 in the through region THR. The second through via 170 may extend in the third direction D3 through the stack of the mold insulating layer 110 and the mold sacrificial film in the through region THR and the string select line stack SS. As another example, the second through via 170 may be disposed outside the first mold stack MS1 and may not penetrate through the first mold stack MS1.

Each of the first through via 160 and the second through via 170 may be connected to or may contact the first wiring structure 190 on the second interlayer insulating film 132. For example, a first inter-wiring insulating film 134 may be formed on the second interlayer insulating film 132. The first wiring structure 190 may be formed in the first inter-wiring insulating film 134. Each of the first through via 160 and the second through via 170 may be connected to or may contact the first wiring structure 190 by a contact via 186. The first wiring structure 190 may be connected to or may contact the bit line BL.

The peripheral circuit region PERI may include a peripheral circuit substrate 400, a peripheral circuit element 460, and a second wiring structure 480.

The peripheral circuit substrate 400 may be disposed below the cell substrate 100 and/or the insulating substrate 101. For example, an upper surface of the peripheral circuit substrate 400 may face a lower surface of the cell substrate 100. For example, the peripheral circuit substrate 400 may include a semiconductor substrate such as a silicon substrate, a germanium substrate, or a silicon-germanium substrate. Alternatively, the peripheral circuit substrate 400 may also include a silicon-on-insulator (SOI) substrate, a germanium-on-insulator (GOI) substrate, etc.

The peripheral circuit element 406 may be formed on the peripheral circuit substrate 400. The peripheral circuit element 406 may form a peripheral circuit that controls the operation of the semiconductor device. For example, the peripheral circuit element 460 may include a control logic, a row decoder, a page buffer, etc. In the following description, the surface of the peripheral circuit substrate 400 on which the peripheral circuit element 460 is disposed may be referred to as a front side of the peripheral circuit substrate 400. Conversely, the surface of the peripheral circuit substrate 400 opposite the front side of the peripheral circuit substrate 400 may be referred to as a back side of the peripheral circuit substrate 400.

For example, the peripheral circuit element 460 may include a transistor, but is not limited thereto. For example, the peripheral circuit element 460 may include not only various active elements such as transistors, but also passive elements such as capacitors, resistors, and inductors.

The back side of the cell substrate 100 may face the front side of the peripheral circuit substrate 400. For example, a second inter-wiring insulating film 430 covering the peripheral circuit element 460 may be formed on the front side of the peripheral circuit substrate 400. The cell substrate 100 and/or the insulating substrate 101 may be stacked on an upper surface of the second inter-wiring insulating film 430.

The first wiring structure 190 may be connected to or may contact the peripheral circuit element 460 through the first through via 160 and/or the second through via 170. For example, the second wiring structure 480 connected to or contacting the peripheral circuit element 460 may be formed in the second inter-wiring insulating film 430. The first through via 160 and/or the second through via 170 may extend in the third direction D3 to connect or contact the first wiring structure 190 to the second wiring structure 480. Accordingly, the bit line BL, each of the gate electrodes 120, and/or the source structures 102 and 104 may be electrically connected to the peripheral circuit element 460.

The second through via 170 may be formed through or penetrating the insulating substrate 101 to connect the first wiring structure 190 to the second wiring structure 480. Accordingly, the second through via 170 may be electrically separated (e.g., insulated) from the cell substrate 100.

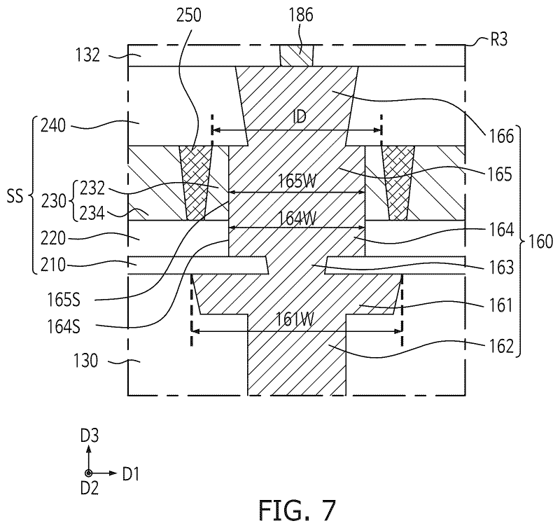

FIGS. 7, 8, and 9 illustrate enlarged views of the region R3 of FIG. 2. The region R3 in FIGS. 7, 8, and 9 may be same as or similar in some respects to the region R3 in FIGS. 1-6, and therefore may be best understood with reference thereto.

A side surface 164S of the fourth portion 164 and a side surface 165S of the fifth portion 165 may be disposed in a same plane. Referring to FIG. 7, the side surface 164S of the fourth portion 164 and the side surface 165S of the fifth portion 165 may be aligned in the third direction D3.

An inner diameter ID of the insulating pattern 250 may not exceed the horizontal width 161W of the first portion 161. Referring to FIG. 7, the inner diameter ID of the insulating pattern 250 may be equal to or less than the horizontal width 161W of a first portion 161. Accordingly, the horizontal width 165W of the fifth portion 165 may be equal to or less than the horizontal width 161W of the first portion 161. In addition, in some example embodiments in which the second string select line insulating layer 220 includes the same material as the insulating pattern 250, the horizontal width 164W of the fourth portion 164 may be equal to or less than the horizontal width 161W of the first portion 161. This may be due to the second string select line insulating layer 220 and the string select line gate layer 230 restricted from being patterned in the horizontal direction (e.g., in the first and second directions D1 and D2) by the insulating pattern 250.

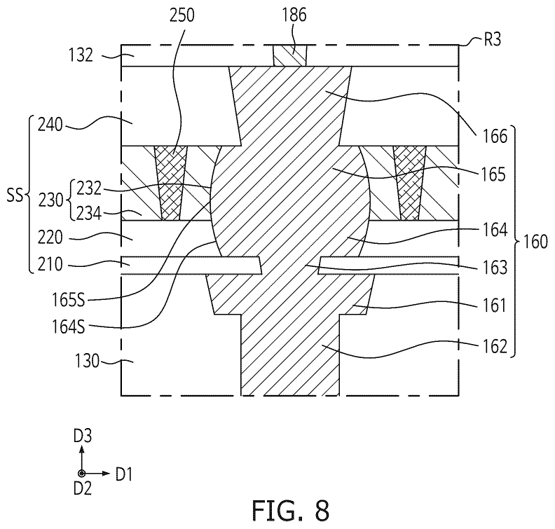

The side surface 164S of the fourth portion 164 and the side surface 165S of the fifth portion 165 may be disposed on the same curved surface. Referring to FIG. 8, the side surface 164S of the fourth portion 164 and the side surface 165S of the fifth portion 165 may together (or cooperatively) define a convex surface of the first through via 160 in the first direction D1.

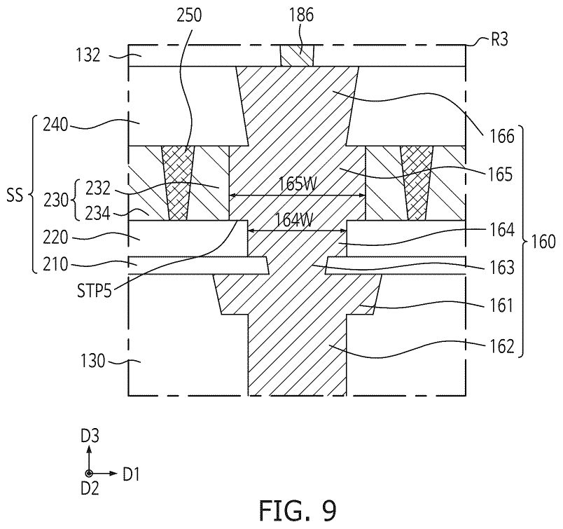

The horizontal width 164W of the fourth portion 164 and the horizontal width 165W of the fifth portion 165 may be different from each other. Referring to FIG. 9, the horizontal width 164W of the fourth portion 164 may be less than the horizontal width 165W of the fifth portion 165. Additionally or alternatively, the side surface of the fourth portion 164 and the side surface of the fifth portion 165 may be misaligned in the third direction D3. For example, the first through via 160 may include a fifth stepped surface STP5 defined by the difference in width between the fourth portion 164 and the fifth portion 165.

This may be due to a difference in etching selectivity between the second string select line insulating layer 220 and the string select line gate layer 230. For example, the string select line gate layer 230, which includes a semiconductor material such as polycrystalline silicon, may be patterned to be larger in the horizontal direction (e.g., the first and second directions D1 and D2) than the second string select line insulating layer 220, which includes silicon oxide.

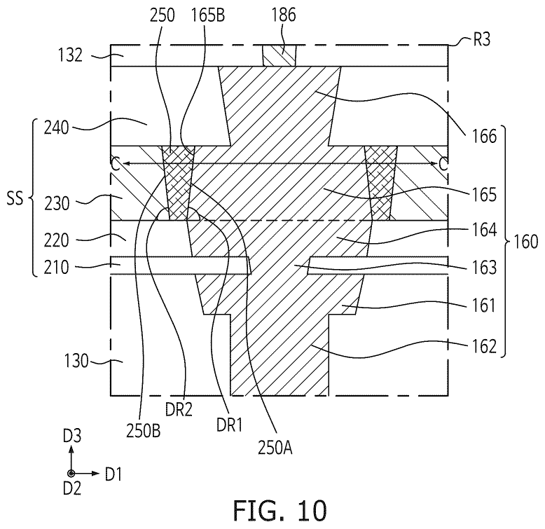

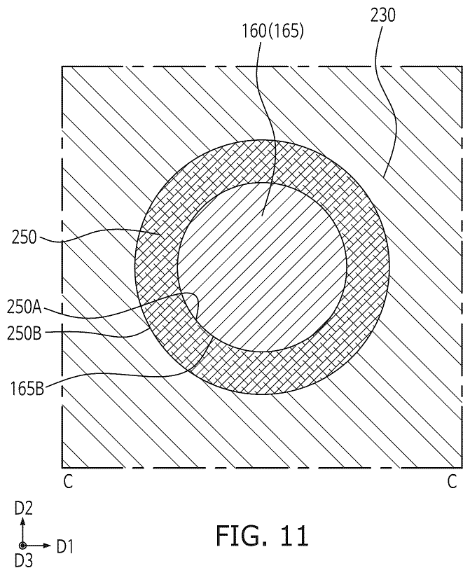

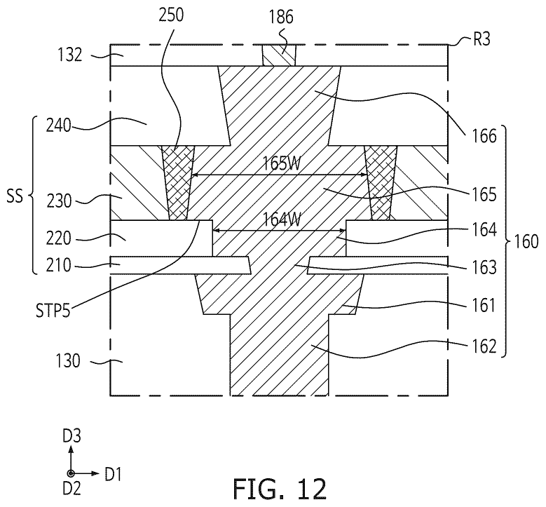

FIGS. 10 and 12 illustrate enlarged views of the region R3 of FIG. 2. FIG. 11 is a cross-sectional view taken along line C-C of FIG. 10. The region R3 in FIGS. 10-12 may be same as or similar in some respects to the region R3 in FIGS. 1-9, and therefore may be best understood with reference thereto.

The string select line gate layer 230 may not be interposed between the insulating pattern 250 and the first through via 160. Referring to FIGS. 10 and 11, an inner surface 250A of the insulating pattern 250 may be connected to or may contact an outer surface 165B of the fifth portion 165.

The inner surface 250A of the insulating pattern 250 and the outer surface 250B of the insulating pattern 250 may be symmetrical to each other and have the same inclination angle. For example, a first angle DR1 between a virtual plane extending from the lower surface of the string select line gate layer 230 and the inner surface 250A of the insulating pattern 250, and a second angle DR2 between the virtual plane extending from the lower surface of the string select line gate layer 230 and the outer surface 250B of the insulating pattern 250 may be the same or substantially the same as each other.

The horizontal width 164W of the fourth portion 164 and the horizontal width 165W of the fifth portion 165 may be different from each other. Referring to FIG. 12, the horizontal width 164W of the fourth portion 164 may be less than the horizontal width 165W of the fifth portion 165. Additionally or alternatively, the side surface of the fourth portion 164 and the side surface of the fifth portion 165 may be misaligned in the third direction D3. For example, the first through via 160 may include the fifth stepped surface STP5 defined by the difference in width between the fourth portion 164 and the fifth portion 165.

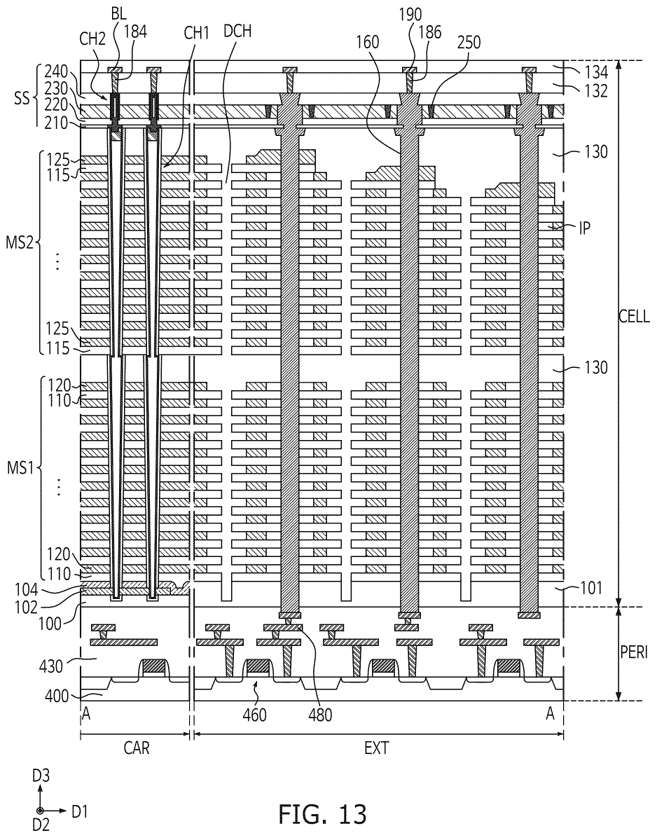

FIG. 13 illustrates a semiconductor device, according to some example embodiments. The semiconductor device in FIG. 13 may be same as or similar in some respects to the semiconductor device in FIGS. 1-12, and therefore may be best understood with reference thereto.

Referring to FIG. 13, in a semiconductor device, according to some example embodiments, a second mold stack MS2 and the first mold stack MS1 may be sequentially stacked on the cell substrate 100 and the insulating substrate 101.

The second mold stack MS2 may be disposed or formed on the first mold stack MS1. The second mold stack MS2 may include a plurality of mold insulating layers 115 and a plurality of gate electrodes 125 alternately stacked in the third direction D3. Each of the mold insulating layers 115 and each of the gate electrodes 125 may have a layered structure extending parallel to the front side of the cell substrate 100.

The channel structure CH1 may extend in the third direction D3 and penetrate through the first mold stack MS1 and the second mold stack MS2. The channel structure CH1 may have a stepped portion between the first mold stack MS1 and the second mold stack MS2. In addition, the first through via 160 may extend in the third direction D3 and penetrate through the first mold stack MS1 and the second mold stack MS2.

FIG. 13 illustrates only two mold stacks MS1 and MS2, but this is merely an example. In some example embodiments, the number of mold stacks MS1 and MS2 may be three or more.

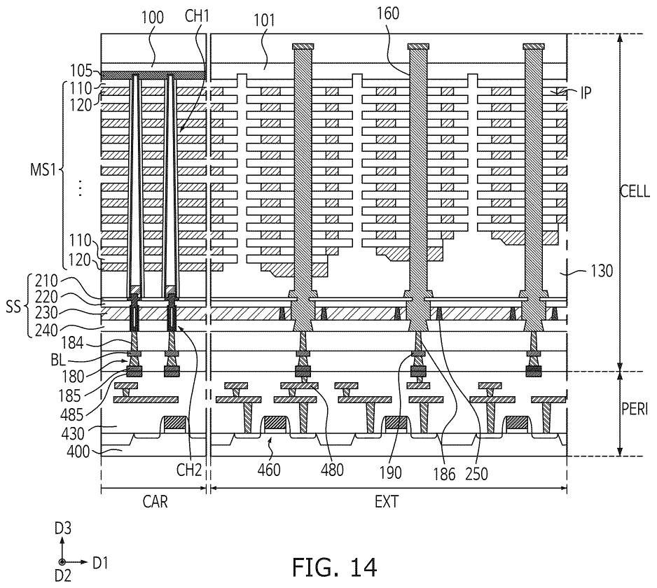

FIG. 14 illustrates a semiconductor device, according to some example embodiments. The semiconductor device in FIG. 14 may be same as or similar in some respects to the semiconductor device in FIGS. 1-13, and therefore may be best understood with reference thereto.

Referring to FIG. 14, the semiconductor device may include a common source plate 105.

The common source plate 105 may be disposed on the front side of the cell substrate 100. The common source plate 105 may be connected to or may contact the channel structure CH1. For example, the common source plate 105 may be electrically connected to or may contact the semiconductor pattern of the channel structure CH1. The common source plate 105 may be used as the common source line (e.g., CSL of FIG. 21) of the semiconductor device. The first mold stack MS1 may be disposed on the common source plate 105. For example, the common source plate 105 may include polycrystalline silicon or metal doped with an impurity, but example embodiments are not limited thereto.

The semiconductor device according to some example embodiments may have a chip-to-chip (C2C) structure. The C2C structure refers to manufacturing an upper chip including the memory cell structure (CELL) on a first wafer (e.g., the cell substrate 100), manufacturing a lower chip including the peripheral circuit structure (PERI) on a second wafer (e.g., the peripheral circuit substrate 400) that is different from the first wafer, and connecting the upper and lower chips to each other by a bonding method.

In some example embodiments, the bonding method may refer to a method of electrically connecting a first bonding metal 185 formed on the uppermost metal layer of the upper chip and a second bonding metal 485 formed on the uppermost metal layer of the lower chip to each other. For example, if the first bonding metal 185 and the second bonding metal 485 are formed of copper (Cu), the bonding method may be a Cu—Cu bonding method. However, this is merely an example, and the first bonding metal 185 and the second bonding metal 485 may include various other metals such as aluminum (Al) and tungsten (W).

As the first bonding metal 185 and the second bonding metal 485 are bonded to each other, a bonding wiring structure 180 may be connected to or may contact the second wiring structure 480. Accordingly, the bit line BL and each of the gate electrodes 120 may be electrically connected to or may contact a peripheral circuit element 460.

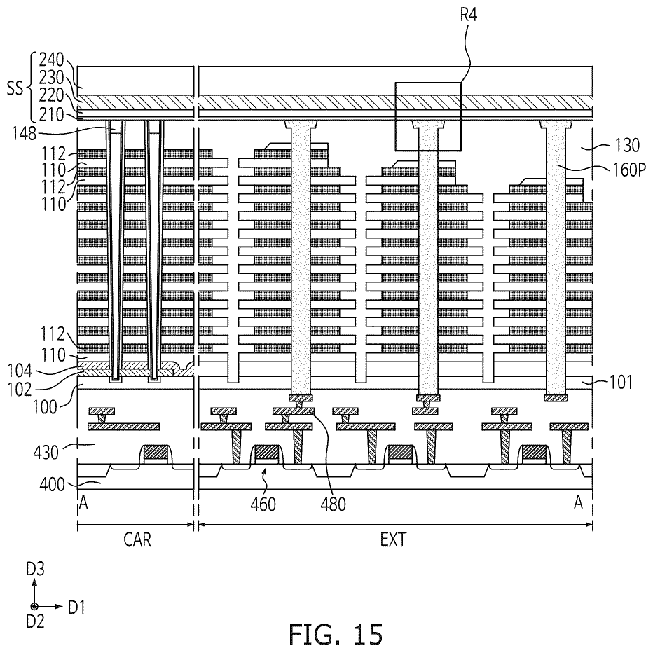

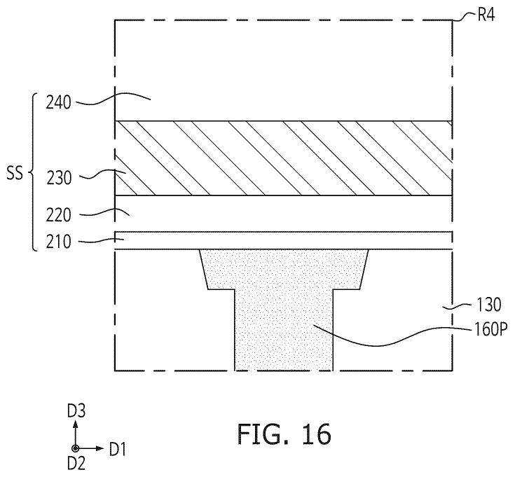

FIGS. 15 to 20 illustrate intermediate stages in a method for manufacturing a semiconductor device. FIG. 15 illustrates a cross-sectional view taken along line A-A of FIG. 1. FIGS. 16 to 20 are enlarged views of a region R4 of FIG. 15.

Referring to FIGS. 15 and 16, a preliminary mold stack may be formed on the cell substrate 100 and the insulating substrate 101. For example, a preliminary mold stack in which the plurality of mold insulating layers 110 and a plurality of mold sacrificial layers 112 are alternately stacked may be provided on the front sides of the cell substrate 100 and the insulating substrate 101. The preliminary mold stack on the extension region EXT may be patterned in a stepped structure.

A first preliminary through via 160P may be formed through or penetrating the preliminary mold stack in the third direction D3. The first preliminary through via 160P may include polysilicon or carbon, but example embodiments are not limited thereto, and a material of the first preliminary through via 160P may be variously changed.

The string select line stack SS may be formed on the preliminary mold stack. For example, the first string select line insulating layer 210, the second string select line insulating layer 220, the string select line gate layer 230, and the third string select line insulating layer 240 may be sequentially stacked or formed on the upper surface of the first interlayer insulating film 130.

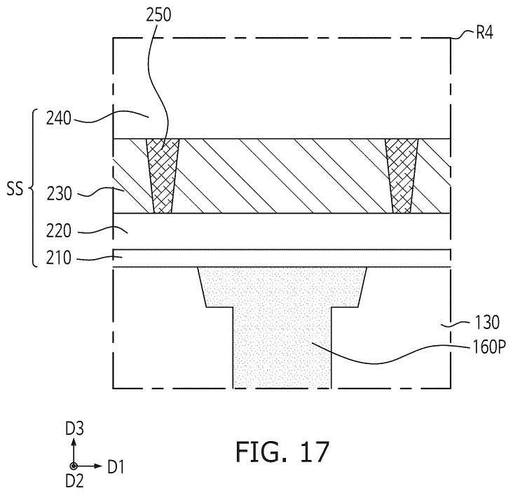

Referring to FIG. 17, the insulating pattern 250 may be formed in the string select line gate layer 230 of the string select line stack SS. The insulating pattern 250 may be formed in a hollow cylindrical or donut shape to surround or extend around a region that overlaps with the first preliminary through via 160P in the third direction D3.

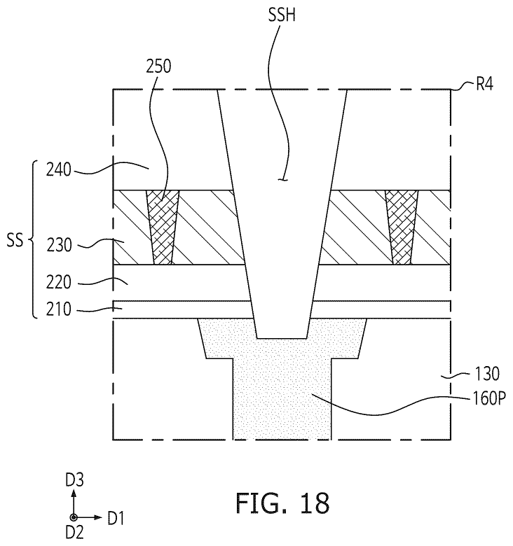

Referring to FIG. 18, a select line stack through hole SSH may be formed through or penetrating the string select line stack SS in the third direction D3. For example, the select line stack through hole SSH, which sequentially penetrates through the third string select line insulating layer 240, the string select line gate layer 230, the second string select line insulating layer 220, and the first string select line insulating layer 210, may be formed. The select line stack through hole SSH may extend up to an upper portion of the first preliminary through via 160P. In addition, the select line stack through hole SSH may be formed in a region surrounded or extended around by the insulating pattern 250.

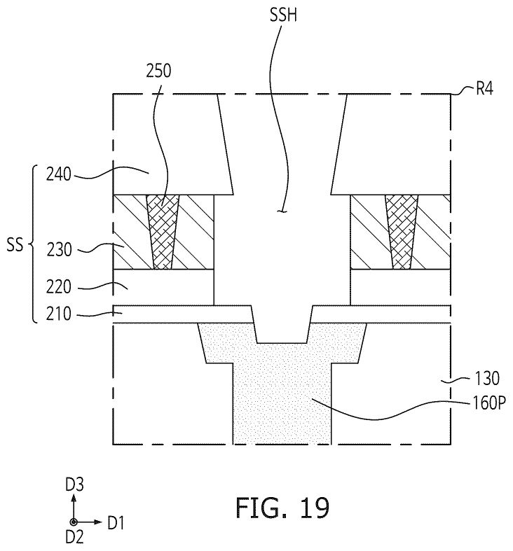

Referring to FIG. 19, the second string select line insulating layer 220 and the string select line gate layer 230 may be patterned in the horizontal direction (e.g., in the first and second directions D1 and D2). For example, the second string select line insulating layer 220 and the string select line gate layer 230 may be patterned from an inner wall of the select line stack through hole SSH in the horizontal direction. Accordingly, a portion of the upper surface of the first string select line insulating layer 210 and a portion of the lower surface of the third string select line insulating layer 240 may be exposed to the outside, forming a stepped surface. Although it is illustrated that only the side surfaces of the second string select line insulating layer 220 and the string select line gate layer 230 are aligned and patterned in the horizontal direction, this is merely an example, and a stepped surface may be formed between the second string select line insulating layer 220 and the string select line gate layer 230 as a result of patterning in the horizontal direction.

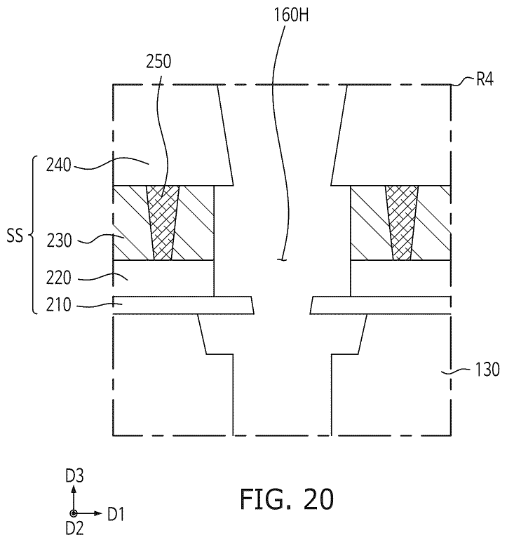

Referring to FIG. 20, the first preliminary through via 160P may be removed, and a first through via hole 160H may be formed. The first through via hole 160H may be filled with a conductive material and the first through via (e.g., the first through via 160 of FIG. 2) may be formed. In addition, the second interlayer insulating film 132 (FIG. 2) and the first inter-wiring insulating film 134 (FIG. 2) may be formed, the first wiring structure 190 may be formed, and the semiconductor device described with reference to FIGS. 1 to 12 may be obtained. In addition, the semiconductor device described with reference to FIGS. 13 to 15 may be obtained using a similar method.

FIG. 21 is a block diagram of an electronic system.

Referring to FIG. 21, an electronic system 1000 may include a semiconductor device 1100 described with reference to FIGS. 1 and 15 and a controller 1200 electrically connected to or contacting the semiconductor device 1100. The electronic system 1000 may be a storage device including one or a plurality of semiconductor devices 1100 or an electronic device including the storage device. For example, the electronic system 1000 may be a solid state drive device (SSD) including one or more semiconductor devices 1100, a universal serial bus (USB), a computing system, a medical device, or a communication device.

The semiconductor device 1100 may be, for example, the NAND flash memory device described above with reference to FIGS. 1 and 15. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including the bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary depending on application and/or design.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to or may contact the decoder circuit 1110 through first connection lines 1115 extending from within the first structure 1100F to the second structure 1100S. The bit lines BL may be electrically connected to or may contact the page buffer 1120 through second connection wires 1125 extending from within the first structure 1100F to the second structure 1100S.

In the first structure 1100F, the decoder circuit 1110 and the page buffer 1120 may perform a control operation on at least one select memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to or contacting the logic circuit 1130. The input/output pad 1101 may be electrically connected to or may contact the logic circuit 1130 through an input/output connection wiring 1135 extending from within the first structure 1100F to the second structure 1100S.

The controller 1200 may include a processor 1210, a NAND controller 1220, and a host interface 1230. According to some example embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to predetermined firmware and may access the semiconductor device 1100 by controlling the NAND controller 1220. The NAND controller 1220 may include a NAND interface (or a controller interface) 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a communication function between the electronic system 1000 and an external host. If a control command is received from an external host through the host interface 1230, the processor 1210 may control the semiconductor device 1100 in response to the control command.

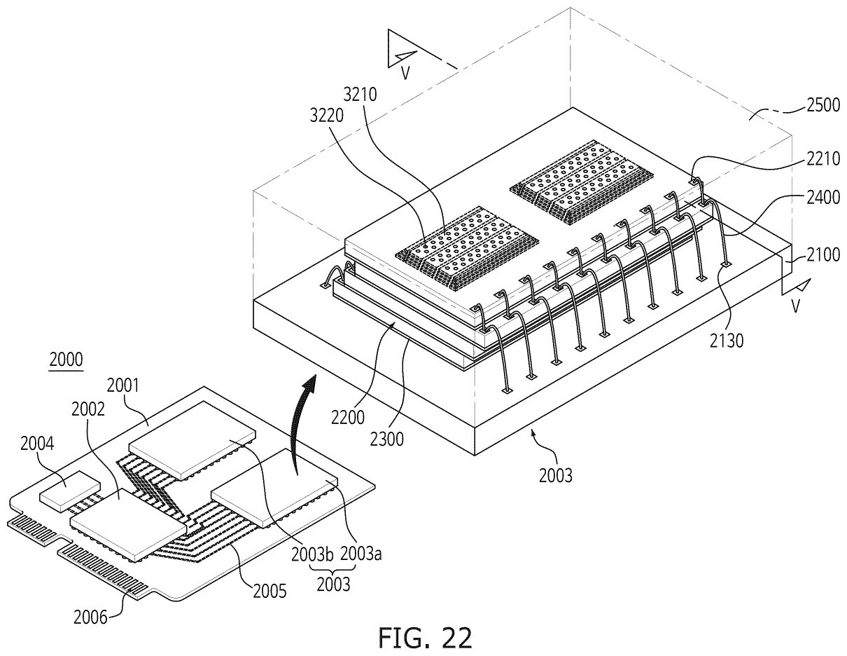

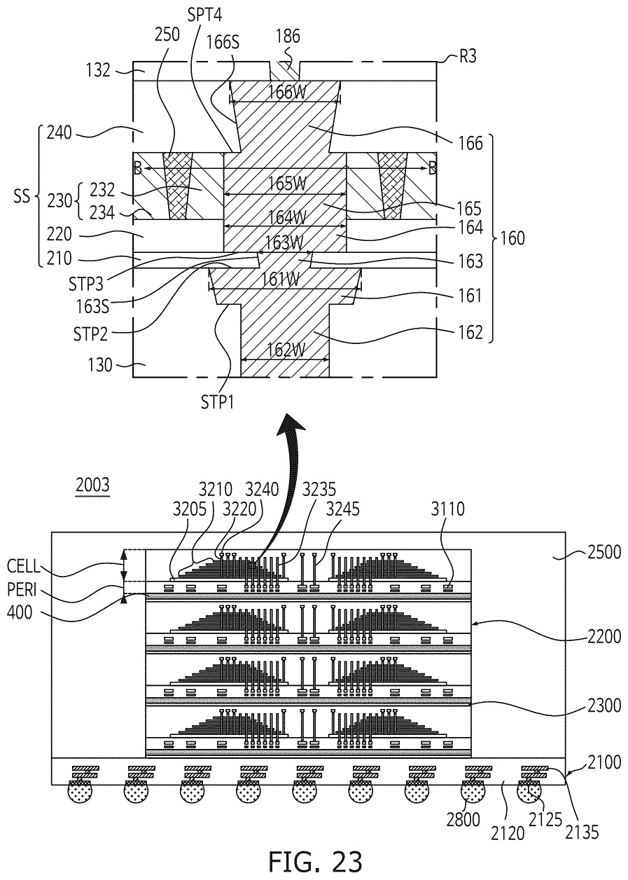

FIG. 22 is an example perspective view illustrating an electronic system 2000 including a semiconductor device. FIG. 23 is a schematic cross-sectional view taken along line V-V of FIG. 22.

Referring to FIGS. 22 and 23, the electronic system 2000 may include a main substrate 2001, a main controller 2002 mounted on the main substrate 2001, one or more semiconductor packages 2003, and a DRAM 2004. The semiconductor package 2003 and the DRAM 2004 may be connected to or contact the main controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some example embodiments, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may be operated by the power supplied from the external host through the connector 2006. The electronic system 2000 may further include a Power Management Integrated Circuit (PMIC) that distributes the power supplied from the external host to the main controller 2002 and the semiconductor package 2003.

The main controller 2002 may write data in the semiconductor package 2003 or read data from the semiconductor package 2003, and may improve the operation speed of the electronic system 2000.

The DRAM 2004 may be a buffer memory to alleviate or reduce the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 21. Each of the semiconductor chips 2200 may include bit lines 3240 and channel structures 3220. Each of the semiconductor chips 2200 may include the semiconductor device described above with reference to FIGS. 1 and 15.

The connection structure 2400 may be a bonding wire electrically connecting the input/output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In each of the first and second semiconductor packages 2003a and 2003b, the semiconductor chips 2200 may be electrically connected to each other through a connection structure including through a through silicon via (TSV) instead of the bonding wire type connection structure 2400.

The main controller 2002 and the semiconductor chips 2200 may be included in one package. The main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

The package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be connected to the wiring patterns 2005 of the main substrate 2001 of the electronic system 2000 through conductive connection portions 2800, as illustrated in FIG. 22.

In the electronic system 2000, each of the semiconductor chips 2200 may include the semiconductor device described above using FIGS. 1 and 15. For example, each of the semiconductor chips 2200 may include the peripheral circuit structure PERI and the cell structure CELL stacked on the peripheral circuit structure PERI. For example, the peripheral circuit structure PERI may include a peripheral circuit substrate 400 described above with reference to FIGS. 1 to 15 and a peripheral wiring 3110. In addition, for example, the cell structure CELL may include a common source line 3205, a gate stack structure 3210 on the common source line 3205, a channel structure 3220 and an isolation structure formed through or penetrating the gate stack structure 3210, a bit line 3240 electrically connected to the channel structure 3220, and a gate connection wiring electrically connected to the word line of the gate stack structure 3210.

Each of the semiconductor chips 2200 may include a plurality of through wirings 3235 and 3245 electrically connected to the peripheral wiring 3110 of the peripheral circuit structure PERI and penetrating the cell structure CELL. The through wirings 3235 and 3245 may be formed through or penetrating the gate stack structure 3210 and may be further disposed outside the gate stack structure 3210. Each of the semiconductor chips 2200 may further include an input/output connection wiring electrically connected to the peripheral wiring 3110 of the peripheral circuit structure PERI and penetrating the cell structure CELL, and the input/output pad 2210 electrically connected to the input/output connection wiring.

Although example embodiments have been described above, example embodiments are not limited thereto, and various modifications and modifications can be made within the same scope of the technical idea of the present disclosure and the claims described below by those with ordinary knowledge in the technical field to which the present disclosure belongs.

Example embodiments are not limited to mutually exclusive. For example, some example embodiments may include features referenced in one or more drawings, and also include one or more other features referenced in other drawings.

What is claimed is:

1. A semiconductor device, comprising:
a substrate;
a mold stack including a plurality of gate electrodes and a plurality of mold insulating layers alternately stacked on the substrate;
an interlayer insulating film on the mold stack;
a string select line stack on the interlayer insulating film and including a string select line gate layer;
a through via penetrating the mold stack, the interlayer insulating film, and the string select line stack; and
an insulating pattern surrounding the through via within the string select line gate layer,
wherein the string select line gate layer includes a first gate portion between an inner surface of the insulating pattern and an outer surface of the through via, and a second gate portion on an outer surface of the insulating pattern.

2. The semiconductor device according to claim 1, wherein the string select line stack further includes:
a first string select line insulating layer on the interlayer insulating film;
a second string select line insulating layer between the first string select line insulating layer and the string select line gate layer; and
a third string select line insulating layer on the string select line gate layer.

3. The semiconductor device according to claim 2, wherein
the through via includes a first portion and a second portion penetrating the interlayer insulating film,
the first portion is below the first string select line insulating layer,
the second portion is below the first portion, and
a horizontal width of the first portion is greater than a horizontal width of the second portion.

4. The semiconductor device according to claim 3, wherein the through via includes a stepped surface defined by a difference in width between the first portion and the second portion.

5. The semiconductor device according to claim 3, wherein
the through via further includes a third portion penetrating the third string select line insulating layer, and
the horizontal width of the first portion is greater than a horizontal width of the third portion.

6. The semiconductor device according to claim 3, wherein
the through via further includes:
a third portion penetrating the first string select line insulating layer; and
a fourth portion penetrating the second string select line insulating layer, and
a horizontal width of the third portion is less than a horizontal width of the first portion and a horizontal width of the fourth portion.

7. The semiconductor device according to claim 2, wherein
the through via includes:
a first portion penetrating the string select line gate layer; and
a second portion penetrating the third string select line insulating layer, and
a horizontal width of the first portion is greater than a horizontal width of the second portion.

8. The semiconductor device according to claim 7, wherein the through via includes a stepped surface defined by a difference in width between the first portion and the second portion.

9. The semiconductor device according to claim 2, wherein
the through via includes:
a first portion penetrating the string select line gate layer; and
a second portion penetrating the second string select line insulating layer, and
a side surface of the first portion and a side surface of the second portion are in a same plane.

10. The semiconductor device according to claim 2, wherein
the through via includes:
a first portion penetrating the string select line gate layer; and
a second portion penetrating the second string select line insulating layer, and
a side surface of the first portion and a side surface of the second portion together define a convex surface.

11. The semiconductor device according to claim 3, wherein an inner diameter of the insulating pattern is equal to or less than the horizontal width of the first portion.

12. The semiconductor device according to claim 2, wherein
the through via includes:
a first portion penetrating the second string select line insulating layer; and
a second portion penetrating the string select line gate layer,
wherein a horizontal width of the second portion is greater than a horizontal width of the first portion.

13. The semiconductor device according to claim 2, wherein
the through via includes,
a first portion penetrating the first string select line insulating layer; and
a second portion penetrating the third string select line insulating layer, and
a side surface of the first portion and a side surface of the second portion have a same inclination angle.

14. The semiconductor device according to claim 1, wherein the inner surface of the insulating pattern and the outer surface of the insulating pattern are symmetrical to each other.

15. The semiconductor device according to claim 1, further comprising a first channel structure penetrating the mold stack, wherein
the first channel structure includes a first semiconductor pattern, a channel pad connected to the first semiconductor pattern, and an information storage film between the first semiconductor pattern and the plurality of gate electrodes.

16. The semiconductor device according to claim 1, further comprising a second channel structure penetrating the string select line stack, wherein
the second channel structure includes a second semiconductor pattern, and a dielectric pattern between the second semiconductor pattern and the string select line gate layer.

17. A semiconductor device, comprising:
a substrate;
a mold stack including a plurality of gate electrodes and a plurality of mold insulating layers alternately stacked on the substrate;
an interlayer insulating film on the mold stack;
a string select line stack on the interlayer insulating film and including a string select line gate layer;
a through via penetrating the mold stack, the interlayer insulating film, and the string select line stack; and
an insulating pattern surrounding the through via within the string select line gate layer,
wherein an inner surface of the insulating pattern and an outer surface of the insulating pattern are symmetrical to each other and have a same inclination angle.

18. The semiconductor device according to claim 17, wherein the string select line stack further includes:
a first string select line insulating layer on the interlayer insulating film;
a second string select line insulating layer between the first string select line insulating layer and the string select line gate layer; and
a third string select line insulating layer on the string select line gate layer.

19. The semiconductor device according to claim 18, wherein
the through via includes:
a first portion penetrating the second string select line insulating layer; and
a second portion penetrating the string select line gate layer, and
a horizontal width of the first portion is less than a horizontal width of the second portion.

20. A semiconductor device, comprising:
a substrate;
a mold stack including a plurality of gate electrodes and a plurality of mold insulating layers alternately stacked on the substrate;
an interlayer insulating film on the mold stack;
a string select line stack including a first string select line insulating layer, a second string select line insulating layer, a string select line gate layer, and a third string select line insulating layer, which are sequentially on the interlayer insulating film;
a through via penetrating the mold stack, the interlayer insulating film, and the string select line stack; and
an insulating pattern surrounding the through via within the string select line gate layer,
wherein the insulating pattern is spaced apart from an outer surface of the through via.
